(19) United States
(12) Patent Application Publication
(10) Pub. No.: US 2025/0298110 A1
(43) Pub. Date: Sep. 25, 2025

(54) MAGNETIC RESONANCE IMAGING APPARATUS AND CENTER FREQUENCY CORRECTION METHOD

(71) Applicant: FUJIFILM Corporation, Tokyo (JP)

(72) Inventor: Atsushi KURATANI, Tokyo (JP)

(73) Assignee: FUJIFILM Corporation, Tokyo (JP)

(21) Appl. No.: 19/050,052

(22) Filed: Feb. 10, 2025

(30) Foreign Application Priority Data
Mar. 22, 2024 (JP) 2024-047187

(51) Int. Cl. G01R 33/565; G01R 33/56

(52) U.S. Cl. CPC G01R 33/56509; G01R 33/5608

(57) ABSTRACT

In a case where misregistration caused by variations in a center frequency is corrected using an amount of phase change calculated using a navigator echo, an influence of a body motion included in the amount of phase change is eliminated to improve accuracy of the correction.

Calculation of a correction value for correcting variations in a center frequency is adjusted while referring to body motion information obtained by detecting a body motion of a subject during an examination. The adjustment is performed using methods such as performing only body motion correction without performing correction while a large body motion occurs, estimating the correction value from a change in a correction value calculated in a case where there is no body motion, or correcting the correction value based on the body motion information.

### CROSS-REFERENCE TO RELATED APPLICATIONS

The present application claims priority under 35 U.S.C. § 119 to Japanese Patent Application No. 2024-047187, filed Mar. 22, 2024. Each of the above application(s) is hereby expressly incorporated by reference, in its entirety, into the present application.

### BACKGROUND OF THE INVENTION

### 1. Field of the Invention

The present invention relates to a technique for correcting variations in frequency that cause nuclear magnetic resonance in a magnetic resonance imaging apparatus (hereinafter, referred to as an MRI apparatus), and more particularly, to a technique for suppressing an influence of a movement (body motion) of an examination target occurring during an examination on frequency variation correction.

### 2. Description of the Related Art

A magnetic resonance imaging apparatus (hereinafter, referred to as an MRI apparatus) generates nuclear magnetic resonance in the atomic nuclei of the atoms that constitute the tissue of an examination target (subject), collects nuclear magnetic resonance signals generated as a result, and reconstructs an image of the subject. In order to induce nuclear magnetic resonance, a radiofrequency pulse having a nuclear magnetic resonance frequency as a center frequency is applied to the subject. The center frequency of the nuclear magnetic resonance frequency is determined depending on a static magnetic field and does not change as long as the static magnetic field intensity is constant. However, due to factors such as heat generation caused by a current flowing through a gradient magnetic field coil, a coil (shim coil) used to correct the static magnetic field may be physically affected, leading to variations in the center frequency. The variations in the center frequency cause the misregistration of the image.

In a case where the variations in the center frequency are known, a phase change can be obtained from these variations, and the misregistration occurring in the image can be corrected using an amount of phase change as a correction value. In the related art, as a method of detecting the variations in the center frequency, there is a method of generating a navigator echo for detecting a phase change separately from an echo for image formation (nuclear magnetic resonance signal) and calculating the phase change using the navigator echo (JP2021-183031A and the like).

In the technique disclosed in JP2021-183031A, whereas an amount of phase change from the generation of the navigator echo to an echo time has been conventionally obtained, a phase change within a measurement time of the navigator echo (data collection time) is acquired, and a difference between the phase change and a phase change of a reference navigator echo acquired in the same manner is taken to calculate the amount of phase change from the reference. In this method, even in a case where an offset (accumulation of temporal changes) occurs in the phase of the navigator echo due to changes over time in eddy currents of a gradient magnetic field, or the like, a deviation from the reference can be accurately obtained without being affected by the offset.

### SUMMARY OF THE INVENTION

According to the method described in JP2021-183031A, the phase change can be accurately obtained, but there are the following problems. The phase change occurs in the navigator echo even in a case where there is a body motion in the subject during imaging, such as a respiratory motion, a heartbeat, or a sudden movement. That is, the phase change calculated from the navigator echo includes both a change caused by variations in the center frequency (a change in the static magnetic field) and a change caused by the body motion. In the case of a periodic motion such as a respiratory motion, since the change is predictable, the change may be separated from the variations in the center frequency.

However, the body motion may include not only periodic movements but also body motions having various magnitudes. Even for the periodic movements, the extent of the influence on the image differs depending on an imaging site. Therefore, it is difficult to separate the phase change caused by the body motion from the phase change caused by the variations in the center frequency, which is the target. In addition, in a case where the body motion is abrupt or very large, it may be difficult to calculate the phase change from the navigator echo itself.

An object of the present invention is to provide a technique capable of specialized detection of variations in a center frequency, thereby enabling accurate separation of a phase change caused by the variations in the center frequency from a phase change caused by a body motion, and allowing for accurate correction of misregistration of an image due to the variations in the center frequency.

Additionally, another object of the present invention is to provide a technique capable of achieving accurate corrections for both the phase changes while separating the phase change caused by the variations in the center frequency from the phase change caused by the body motion.

The present invention uses a navigator echo for detecting a phase change and optical means for detecting a body motion of a subject, for example, a camera, in combination, acquires body motion information from the optical means, uses the body motion information to determine whether or not selection of the navigator echo to be used for calculating the phase change, calculation of a correction value, or the like is necessary, and obtains phase information in which a phase change caused by the body motion is eliminated. As a result, variations in a center frequency are accurately grasped and corrected.

That is, according to an aspect of the present invention, there is provided an MRI apparatus comprising: an imaging unit that collects a nuclear magnetic resonance signal generated from a subject through nuclear magnetic resonance; a computing unit including an image generation unit that reconstructs an image of the subject using the nuclear magnetic resonance signal; and a body motion processing unit that collects body motion information of the subject. The imaging unit collects a navigator echo for detecting a variation in a center frequency of the nuclear magnetic resonance, and the computing unit includes a correction value calculation unit that calculates a correction value for correcting the variation in the center frequency by using a phase change of the navigator echo collected by the imaging unit. The correction value calculation unit calculates the correction value by eliminating an influence of a body motion with reference to the body motion information collected by the body motion processing unit.

In addition, according to another aspect of the present invention, there is provided a center frequency correction method comprising the following steps:
a step of calculating a correction value for the center frequency by calculating a phase difference using two or more nuclear magnetic resonance signals acquired as navigator echoes from a subject during an examination; and a step of collecting body motion information from a device that detects a body motion of the subject during the examination. In the step of calculating the correction value, the correction value is calculated by eliminating an influence of the body motion with reference to the body motion information.

In the present specification, correction for the variations in the center frequency will be referred to as “frequency variation correction”, and correction for the influence of the body motion of the subject on the image will be referred to as “body motion correction”.

According to the aspects of the present invention, in a case of calculating the correction value from the phase change of the navigator echo, by referring to the body motion information in a case where the navigator echo is acquired, it is possible to determine whether or not the acquired navigator echo can be used for calculating the correction value, or whether or not correction or estimation of the correction value is necessary, and it is possible to eliminate the influence of the body motion from the correction value calculated using the navigator echo, thereby achieving accurate frequency variation correction.

### BRIEF DESCRIPTION OF THE DRAWINGS

FIG. 1 is a block diagram showing an example of an overall configuration of an MRI apparatus according to an embodiment of the present invention.

FIG. 2 is a block diagram showing an overall configuration of the MRI apparatus including details of an imaging unit.

FIG. 3 is a flowchart of processing of the MRI apparatus of FIG. 1.

FIG. 4 is a flowchart of processing 1 of Embodiment 1.

FIG. 5 is a flowchart of processing 2 or processing 3 of Embodiment 1.

FIGS. 6A to 6C are graphs illustrating examples of body motion information, in which FIG. 6A is an example of an abrupt body motion, FIG. 6B is an example of a periodic motion, and FIG. 6C is an example in which a change in position has occurred due to a body motion.

FIG. 7 is a graph showing a change in frequency along a time axis.

FIG. 8 is a flowchart showing an example of a flow of processing selection of Embodiment 1.

FIG. 9 is a graph illustrating a modification example of Embodiment 1.

FIG. 10 is a flowchart of processing of Embodiment 2.

FIG. 11A is a graph showing a state in which a periodic motion shown in FIG. 11B is superimposed on frequency variations.

FIGS. 12A and 12B are graphs illustrating processing of Embodiment 2.

FIGS. 13A and 13B are graphs showing an example of a calculation method of a correction value in a case where there is a periodic motion.

FIG. 14 is a flowchart of processing of Embodiment 3.

FIG. 15 is a diagram illustrating the processing of Embodiment 3.

### DESCRIPTION OF THE PREFERRED EMBODIMENTS

Hereinafter, embodiments of an MRI apparatus according to the present invention will be described with reference to drawings. In all the drawings illustrating the embodiments of the invention, components having the same function are assigned the same reference numerals, and repetitive descriptions will not be repeated.

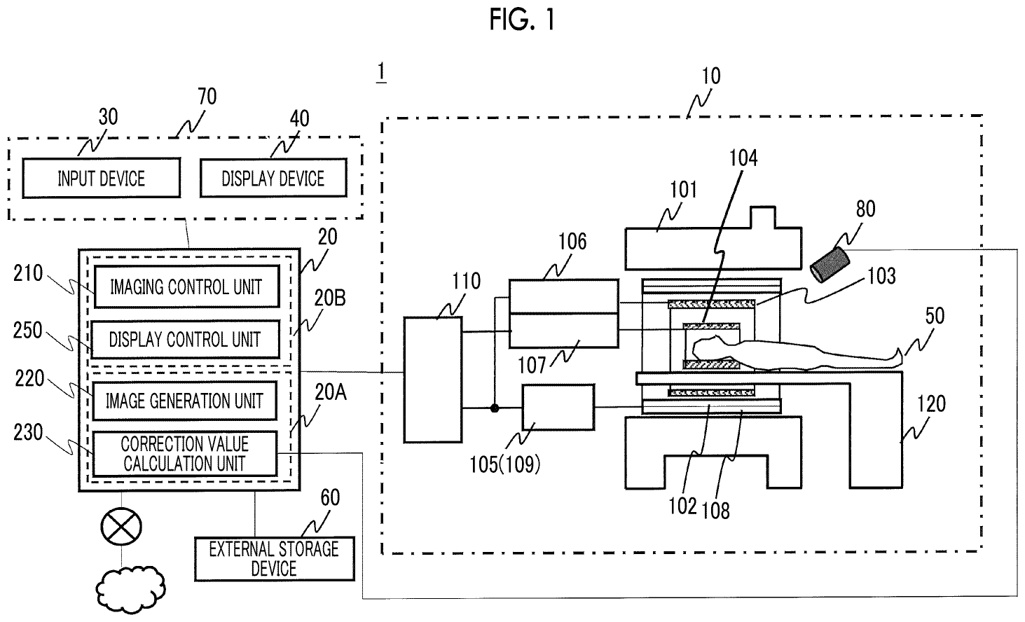

First, an outline of one embodiment of the MRI apparatus according to the present invention will be described. FIG. 1 is a block diagram showing an overall configuration of the MRI apparatus. As shown in FIG. 1, an MRI apparatus 1 of the present embodiment comprises, as a main configuration, an imaging unit 10 and a processor 20 that performs imaging control and computational operations such as image reconstruction.

The imaging unit 10 has the same configuration as a general MRI apparatus and comprises a static magnetic field generation unit 101 that generates a static magnetic field in a space in which a subject is placed, a gradient magnetic field generation unit (102, 105) that applies a magnetic field gradient to the static magnetic field, a transmission unit 106 that irradiates the subject with a radiofrequency magnetic field, a reception unit 107 that receives a nuclear magnetic resonance signal generated from the subject through nuclear magnetic resonance, and the like. Further, a patient table device 120 for positioning the subject in an imaging space is provided.

In the static magnetic field generation unit 101, a static magnetic field generation source of a permanent magnet type, a normal conducting type, or a superconducting type is disposed, and a uniform static magnetic field is generated in a direction orthogonal to a body axis in a space around a subject 50 in a case of a vertical magnetic field type, and a uniform static magnetic field is generated in a body axis direction in a case of a horizontal magnetic field type. In addition, a shim coil 108 for correcting the inhomogeneity of the static magnetic field is disposed in the vicinity of the static magnetic field generation source. The shim coil 108 is connected to a shim power supply 109 and is driven by a current supplied from the shim power supply 109 to generate a correction magnetic field. Hereinafter, the shim coil 108 and the shim power supply 109 will be collectively referred to as a shimming unit. The correction magnetic field generated by the shimming unit can correct the inhomogeneity of the static magnetic field and can correct temporal variations in the static magnetic field. The function of the shimming unit may be performed by the gradient magnetic field generation unit.

The gradient magnetic field generation unit consists of gradient magnetic field coils 102 wound in three-axis directions of X, Y, and Z, which are a coordinate system (stationary coordinate system) of the MRI apparatus, and a gradient magnetic field power supply 105 that drives each of the gradient magnetic field coils, and applies gradient magnetic fields Gx, Gy, and Gz in the three-axis directions of X, Y, and Z by driving the gradient magnetic field power supply 105 of each coil in accordance with a command from a sequencer 110, which will be described below. Upon the imaging, a slice direction gradient magnetic field pulse (Gs) is applied in a direction orthogonal to a slice plane (imaging cross section) to set the slice plane for the subject 50, and a phase encoding direction gradient magnetic field pulse (Gp) and a frequency encoding direction gradient magnetic field pulse (Gf) are applied in the remaining two directions orthogonal to the slice plane and orthogonal to each other, thereby encoding position information in each direction into an echo signal.

The transmission unit 106 irradiates the subject 50 with an RF pulse in order to induce nuclear magnetic resonance in the atomic nuclear spins of the atoms that constitute the biological tissue of the subject 50, and includes a radiofrequency oscillator, a modulator, a radiofrequency amplifier, and a transmission-side radiofrequency coil (transmit coil) 103. The radiofrequency pulse output from the radiofrequency oscillator is amplitude-modulated by the modulator according to a timing as instructed by the sequencer 110, and the amplitude-modulated radiofrequency pulse is amplified by the radiofrequency amplifier and then supplied to the transmit coil 103 disposed in proximity to the subject 50, thereby irradiating the subject 50 with the RF pulse. The nuclear magnetic resonance frequency (center frequency) can be adjusted by adjusting the radiofrequency generated by the radiofrequency oscillator.

The reception unit 107 detects an echo signal (NMR signal) emitted through nuclear magnetic resonance of the atomic nuclear spins that constitute the biological tissue of the subject 50, and includes a signal amplifier, a quadrature phase detector, an A/D converter, and the like, and a reception-side radiofrequency coil (receive coil) 104 is connected thereto. The NMR signal, which is the response of the subject 50 induced by electromagnetic waves emitted from the transmission-side radiofrequency coil (transmit coil) 103, is detected by the receive coil 104 disposed in proximity to the subject 50, amplified by the signal amplifier, and then split into two orthogonal phase signals by the quadrature phase detector according to the timing as instructed by the sequencer 110, and each signal is converted into a digital quantity by the A/D converter and sent as measurement data to the processor 20.

The sequencer 110 is control means for repeatedly applying a radiofrequency magnetic field pulse (hereinafter, referred to as an “RF pulse”) and a gradient magnetic field pulse in a predetermined pulse sequence, operates under the control of the processor 20 (control unit), sends various commands required to collect data of a tomographic image of the subject 50 to the transmission unit 106, the shimming unit, the gradient magnetic field generation unit, and the reception unit 107. Various pulse sequences are prepared depending on the imaging method, and in a case where the imaging method is determined upon the imaging, the processor 20 reads the corresponding pulse sequence and sets the pulse sequence in the sequencer 110. In the present embodiment, a pulse sequence in which the generation and collection of a navigator echo are added is executed.

The processor 20 performs various types of data processing, display and storage of processing results, and the like and includes a control unit 20B and a computing unit 20A. The control unit 20B includes an imaging control unit 210 and a display control unit 250.

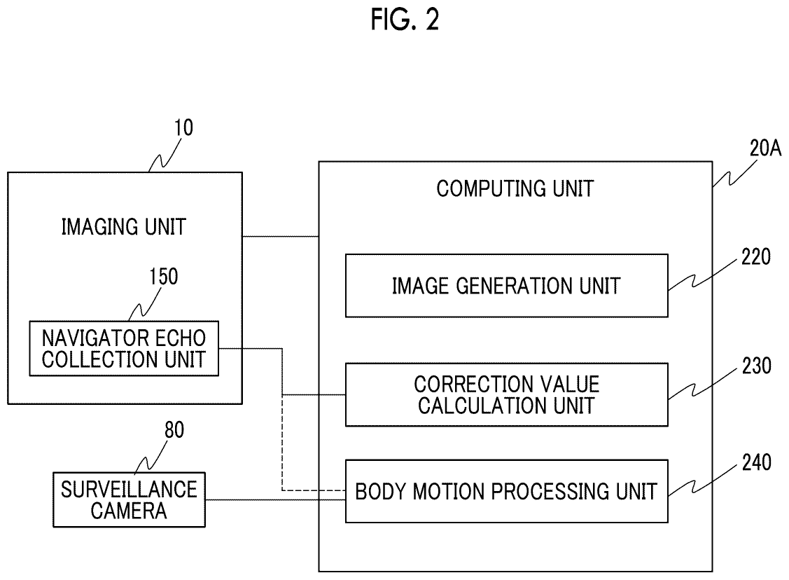

As shown in FIG. 2, the computing unit 20A includes an image generation unit 220 that generates an image using the NMR signal received by the reception unit 107, a correction value calculation unit 230 that uses the navigator echo to calculate a correction value for correcting a variation in the center frequency of the radiofrequency magnetic field for inducing nuclear magnetic resonance, and a body motion processing unit 240 that collects body motion information in order to suppress the influence of the body motion occurring in the subject 50 during the examination and that performs processing necessary for body motion correction.

The functions of each unit of the processor 20 are mainly implemented by a CPU, but some functions can also be implemented by an ASIC or a programmable IC such as an FPGA. An external storage device 60 such as an optical disk or a magnetic disk and a UI unit 70 comprising a display device 40 and an input device 30 are connected to the processor 20. The external storage device 60 includes not only a storage device connected directly or in a wired manner but also a storage device connected wirelessly, or via the Internet or the like.

Additionally, the MRI apparatus 1 comprises optical detection means such as a surveillance camera 80 for monitoring the state of the subject 50 disposed in the static magnetic field space, and the body motion processing unit 240 detects the body motion of the subject 50 by using a video from the surveillance camera 80.

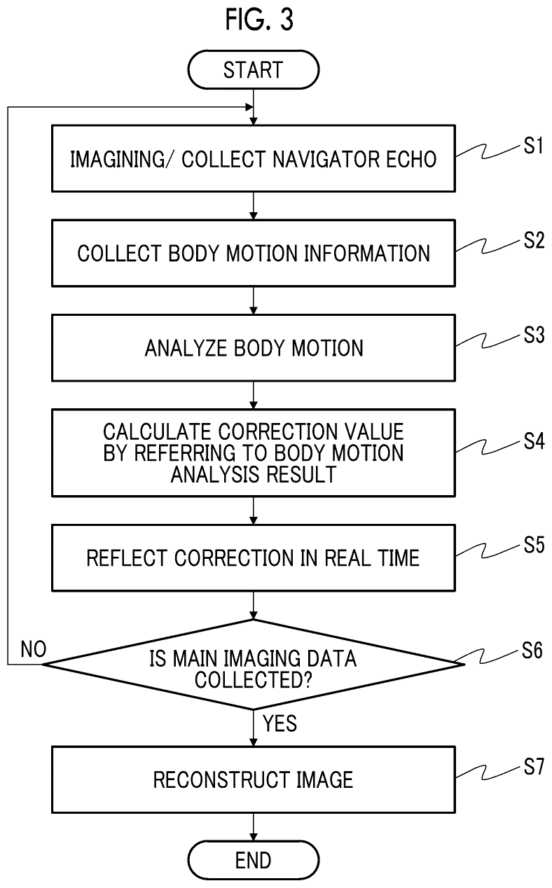

Next, based on the configuration of the MRI apparatus mentioned above, an embodiment of processing from imaging to image reconstruction will be described with reference to FIG. 3.

In a case where the subject is disposed in the imaging space and the imaging is started, an imaging sequence including a navigator sequence for acquiring the navigator echo is executed under the control of the sequencer 110, and the navigator echo and an echo for a subject image (hereinafter, referred to as a main imaging echo) are collected in a time-series manner (S1).

The navigator echo is an NMR signal that is collected in order to detect a phase change occurring in the NMR signal due to variations in the center resonance frequency without applying gradient magnetic fields for phase encoding and readout encoding, and may be acquired before or after acquisition of the main imaging echo within the TR of the pulse sequence for acquiring the main imaging echo or may be acquired by inserting the sequence for acquiring the navigator echo between the TR and the TR of the pulse sequence for acquiring the main imaging echo. Examples of the latter include a sequence disclosed in JP2021-183031A, but the present invention is not limited thereto. In a navigation sequence described in JP2021-183031A, a navigator echo is collected as an FID before the main imaging sequence.

The surveillance camera 80 that detects the movement of the subject is operated at the same time as the start of imaging or prior to the imaging. The body motion processing unit 240 obtains the video of the surveillance camera 80 and analyzes the video, thereby collecting the body motion information of the subject (S2, S3). The body motion includes periodic movements such as a respiratory motion or a heartbeat, which has a small magnitude, unexpected movements of the subject such as coughing, sneezing, and convulsions, and other fine movements. The body motion processing unit 240 detects various body motions by, for example, using known techniques such as optical flow to calculate displacement vectors between frames of the video for changes between the frames and calculating the displacement of each site from the displacement vectors. In this case, a region including an imaging site may be set as an ROI, or the displacement of one or a plurality of feature points of the imaging site may be tracked. By performing such analysis on the video that changes over time, it is possible to acquire, as the body motion information, for example, the magnitude of the movement of each site (feature point) in the ROI, the duration of the movement, and the period or the magnitude of the displacement (an absolute value or a relative value) of each time phase within the period in a case of the periodic motion.

Meanwhile, the correction value calculation unit 230 uses the navigator echo collected through the execution (S2) of the navigator sequence to calculate the correction value for correcting the misregistration caused by the variations in the center frequency (S4). The correction of the misregistration caused by the variations in the center frequency will be hereinafter referred to as frequency variation correction. The correction value calculation unit 230 first calculates an amount of phase change by using the navigator echo in order to calculate the correction value. The amount of phase change is calculated as a difference between a phase of a reference navigator echo and a phase of a navigator echo acquired after the reference navigator echo. A method of calculating the phase difference from the reference navigator echo is not limited, and for example, the method disclosed in JP2021-183031A can be used.

In this method, the phase change at the echo collection time (the time at which the generated echo is sampled) is obtained for both the reference navigator echo and the navigator echo for which the phase difference from the reference navigator echo is to be obtained, and the difference between the phase changes (within the sampling time) is calculated, thereby calculating the amount of phase change relative to the reference. By employing this method, unlike the method of calculating the amount of phase change for each echo time (TE), even in a case where there is accumulated offset in the frequency variations, the amount of phase change relative to the reference can be calculated without being affected by the offset. Therefore, it is preferable to employ the above-described method for the calculation of the amount of phase change by the correction value calculation unit 230 of the present embodiment, but the present invention is not limited to this method, and a known method in the related art can also be employed.

Next, a correction value to be used for frequency variation correction is calculated from the amount of phase change. The frequency variation correction can be performed both as system-side correction (correction during measurement) and image-based correction (correction after measurement). The system-side correction corrects the frequency variations by correcting the current flowing through the shim coil 108 or correcting the center frequency during the irradiation with the RF pulse applied to the subject. That is, the correction value calculation unit 230 calculates at least one of a correction value for the shim current flowing through the shim coil 108 or a correction value for the center frequency during irradiation with the excitation pulse applied by the transmit coil 103.

Specifically, the correction value for the frequency can be calculated from a relational equation (ω=2πf) between a phase (ωt) and a frequency (f). In addition, since the relationship between the current value flowing through the shim coil 108 and the magnetic field intensity generated by the current value is determined by the characteristics of the shim coil 108, the correction current for the shim coil 108 can be calculated from a variation amount of the static magnetic field calculated from a relational equation (f0=λB0) (λ: Larmor frequency) between a magnetic resonance frequency (f0) and a static magnetic field intensity (B0).

The calculated correction value is reflected in the main imaging after the navigator echo used to calculate the correction value (S5). That is, immediately after the correction value is calculated, the main imaging continues under the condition that the shim current or the center frequency of the excitation RF pulse is corrected.

In the case of the correction after the measurement, the correction value is calculated using a linear relationship between the static magnetic field (center frequency) and the position in the real space. That is, the misregistration in the real space corresponding to the magnetic field variation amount is calculated from this relationship, and the correction value for correcting the misregistration on the image is calculated. The correction value is used in a case where main imaging data that can be reconstructed into an image is collected and the image generation unit 220 performs image reconstruction, and the misregistration correction is performed (S6, S7).

In a case where the correction value calculation unit 230 of the present embodiment determines that there is a body motion that affects the calculation of the amount of phase change with reference to the body motion information collected by the body motion processing unit 240 when calculating the amount of phase change and the correction value based on the amount of phase change as mentioned above, the correction value calculation unit 230 adds a change for removing the influence of the body motion from the calculated amount of phase change or correction value.

In a case where there is no body motion, the amount of phase change changes almost linearly over time with a gentle slope due to the frequency variations; however, for example, in the navigator echo acquired in a case where the magnitude of the body motion is large, a change larger than the phase change caused by the frequency variations mentioned above occurs, thereby making it difficult to calculate an accurate amount of phase change. In addition, in a case where the magnitude of the body motion is not large but there is a periodic motion, the change caused by the periodic motion is superimposed and detected in the phase change obtained from the navigator echo. Even in a case where the amount of phase change is calculated in a state in which the influence of the body motion is included, an accurate amount of phase change cannot be calculated.

The correction value calculation unit 230 refers to the body motion information collected from the camera video by the body motion processing unit 240 to determine whether or not the body motion affects the frequency variation correction, and performs processing corresponding to the body motion, such as not performing the frequency variation correction or correcting the correction value. Additionally, since it is also necessary to correct the influence of the body motion itself on the image depending on the body motion, the body motion correction is performed separately from the frequency variation correction. Details of the determination performed by the correction value calculation unit 230 and processing executed as a result of the determination will be described in the embodiment to be described below.

As described above, the MRI apparatus of the present embodiment has, as a function of the computing unit, a function (correction value calculation unit) of calculating the correction value for correcting the frequency variations using the navigator echo and a function (body motion processing unit) of collecting the body motion information of the subject during the examination and performing processing, and the correction value calculation unit refers to the body motion information obtained by the body motion processing unit to determine whether or not the correction value using the navigator echo can be calculated, whether or not the correction of the correction value is necessary, whether or not the body motion correction is necessary, or the like, and reflects the determination in the subsequent imaging.

Consequently, by separating the amount of phase change included in the navigator echo into an amount of phase change caused by the frequency variations and an amount of phase change caused by the body motion, it is possible to accurately calculate the amount of phase change caused by the frequency variations and to perform the correction. In addition, it is possible to perform appropriate body motion correction according to the body motion. As a result, it is possible to obtain a high-quality image in which the influence of the frequency variations is eliminated and the influence of the body motion is suppressed.

Next, a specific embodiment of the correction processing with reference to the body motion information will be described. In the following embodiments, configurations to be used in common to the configurations illustrated in FIGS. 1 and 2 will be described without being shown, and these drawings will be referred to as appropriate.

### Embodiment 1

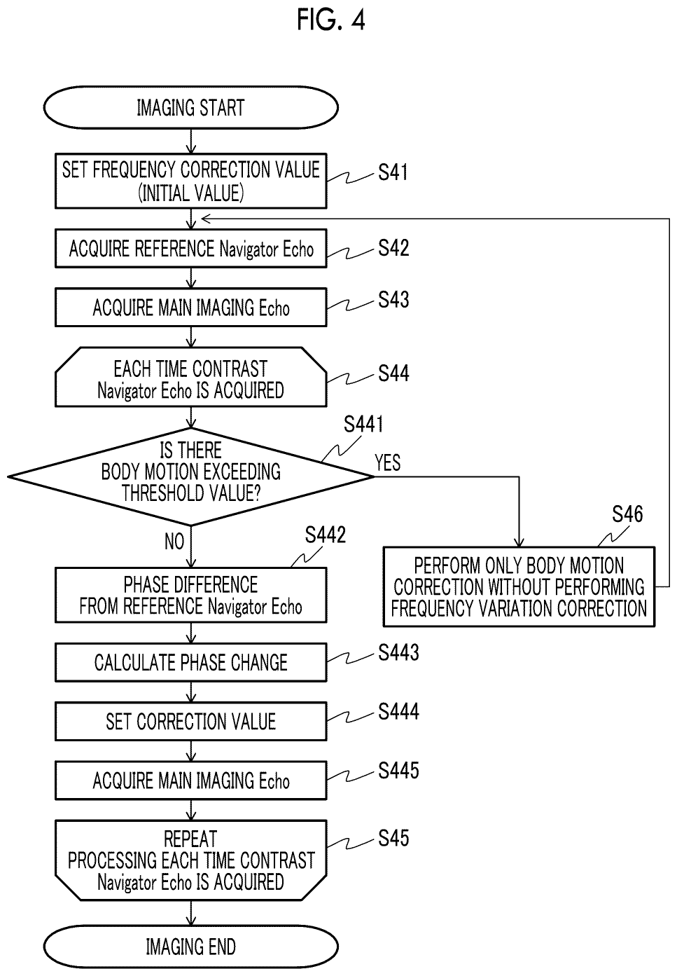

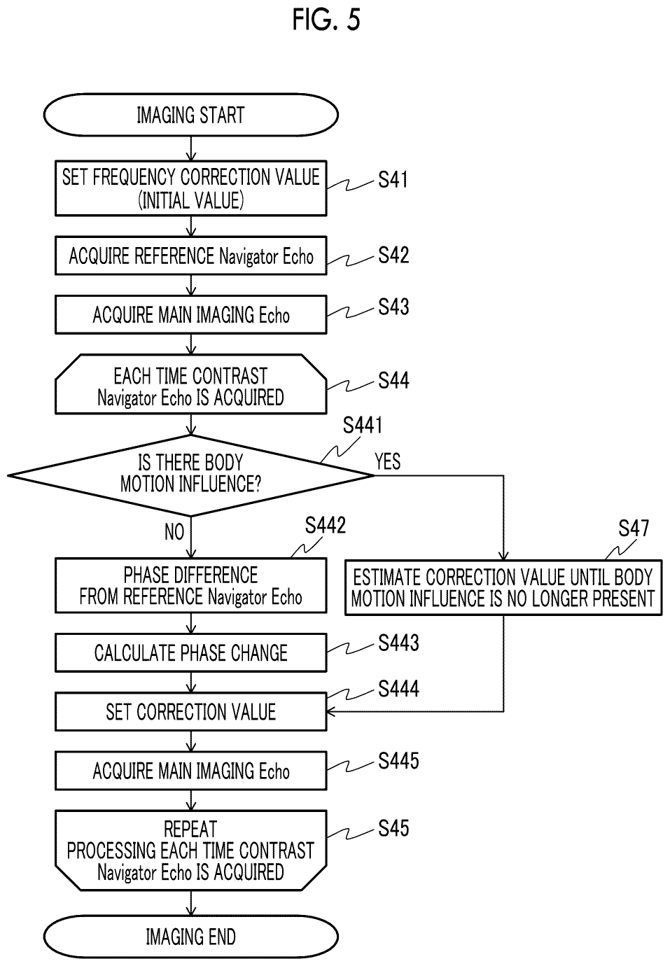

In the present embodiment, the body motion processing unit 240 obtains the magnitude of the body motion, that is, the magnitude of the displacement, as the body motion information from the video of the surveillance camera 80, and changes the processing depending on the magnitude of the body motion. Hereinafter, processing performed by the computing unit 20A will be mainly described with reference to the processing flows shown in FIGS. 4 and 5. In the processing shown in FIGS. 4 and 5, descriptions of processing having the same content as the processing shown in FIG. 3 will not be repeated, and the description will focus on the differences.

The flowcharts shown in FIGS. 4 and 5 are processing flows that are different in processing after determining that there is an influence of the body motion with reference to the body motion information, and the common processing (S41 to S45) in the processing flows of FIGS. 4 and 5 will first be described.

In a case where the imaging is started, an initial value of a frequency correction value is set (S41). The frequency correction value is a correction value for correcting the variations in the frequency and is a correction value for the shim current or a correction value for the emitted center frequency. The initial value is set to zero at the start of imaging. In a case where the frequency variation offset is already known, a correction value calculated from the offset may be set as the initial value.

The navigator sequence is executed with the start of imaging by the imaging unit 10, and a navigator echo collection unit 150 acquires the first navigator echo (S42). The first navigator echo is set as the reference navigator echo. Subsequently, the main imaging echo is acquired (S43), and the next navigator echo is acquired (S44). The navigator echo acquired after the reference navigator echo is acquired is a navigator echo for detecting the phase change after the reference navigator echo is acquired, and here, this will be referred to as a contrast navigator echo.

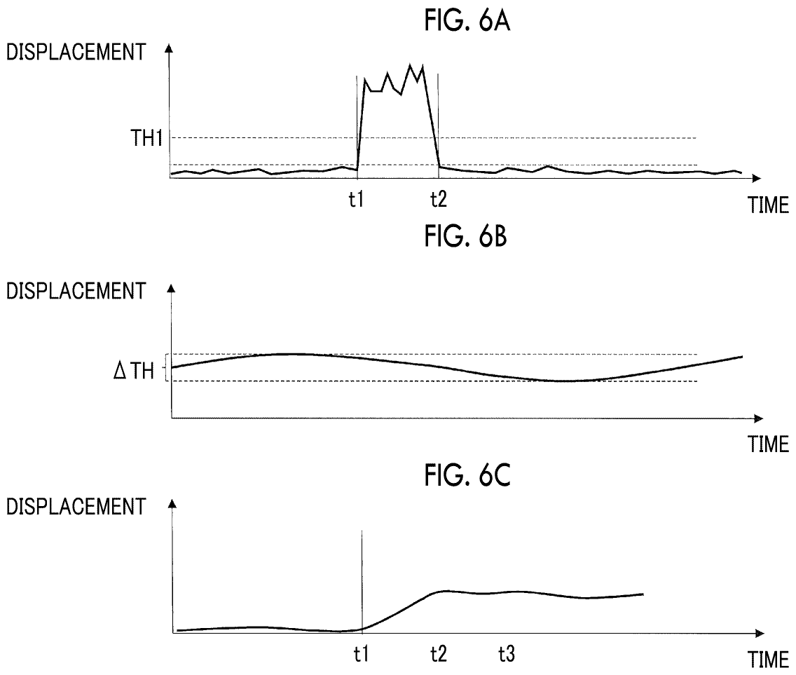

The correction value calculation unit 230 refers to the body motion information acquired by the body motion processing unit 240 so far to determine whether or not the body motion occurs when the contrast navigator echo is acquired (S441). The body motion information is information indicating variations such as a displacement of a predetermined site or an average value of a displacement of a predetermined region with respect to a time axis, and includes, for example, a large movement (abrupt change) for a short time as shown in FIG. 6A, a periodic motion as shown in FIG. 6B, a positional shift as shown in FIG. 6C, and the like. The obtained displacement may be any of an absolute value or a relative value. In contrast, a predetermined threshold value, for example, an absolute value or a relative value of the body motion that affects the calculation of the amount of phase change or the body motion that affects the image (a value obtained empirically or through simulations or the like), is set as a threshold value, and in a case where the body motion exceeds the threshold value, it is determined that there is a body motion influence, and in a case where the body motion is equal to or less than the threshold value, it is determined that there is no body motion influence.

The abrupt body motion can also be detected directly from the phase change of the navigator echo instead of or in addition to the body motion information obtained from the camera video. For example, a threshold value (second threshold value) may be set separately from a threshold value (first threshold value) of the body motion in the camera video for the difference in the phase change of the navigator echo (the difference from the reference navigator echo), and in a case where the difference in the phase change obtained from the navigator echo is equal to or greater than the second threshold value, or in a case where the displacement of the body motion is equal to or greater than the first threshold value and the difference in the phase change is equal to or greater than the second threshold value, it may be determined that there is an abrupt change in the body motion. A plurality of threshold values may be set, thereby allowing for responses tailored to the type and nature of the body motion.

In the present embodiment, an example will be described in which a case where there is an abrupt body motion is determined as a case where there is a body motion influence.

In a case where there is no body motion influence, as described in the flow of FIG. 3, a phase difference between the reference navigator echo and the contrast navigator echo is obtained to calculate the amount of phase change, and the correction value is set (S442 to S444). That is, the correction value set as the initial value is updated. Consequently, the main imaging echo is acquired at the center frequency of the shim current or the RF irradiation, which has been changed in accordance with the correction value (S445). S441 to S444 are repeated each time the contrast navigator echo is acquired (S45).

On the other hand, as a result of referring to the body motion information, in a case where it is determined that there is a body motion at a time point when the contrast navigator echo is acquired, the body motion information is continuously collected, and processing, which is different from the center frequency correction in a case where there is no body motion influence, is performed until the influence of the body motion is no longer present. The different processing is not limited, but for example, any of the following three processing is performed.

In processing 1, the contrast navigator echo affected by the body motion is not used, and the center frequency correction is not performed (FIG. 4).

In processing 2, the contrast navigator echo affected by the body motion is not used, and estimation is performed using the information on the frequency variations acquired prior to the contrast navigator echo affected by the body motion (FIG. 5).

In processing 3, the correction value calculated from the contrast navigator echo affected by the body motion is corrected using the body motion information acquired from the camera video or the like (FIG. 5).

It should be noted that the threshold value for determining the magnitude of the body motion may be different or the same between the processing 1 and the processing 2 or the processing 3.

Hereinafter, each processing will be described.

### Processing 1

In the processing 1, S442 to S444 are resumed at a time point when the influence of the body motion is no longer present, and the center frequency correction is performed. Since slight frequency variations may occur during a period from when it is determined that there is a body motion influence until it is determined that there is no body motion influence, the navigator echo acquired first after the resumption is set as the reference navigator echo (S42), and the amount of phase change is calculated using the reference navigator echo and the navigator echo (contrast navigator echo) acquired after the first navigator echo (S442, S443) and the correction value is set (S444). As shown in FIG. 6C, in a case where the subject is shifted due to the body motion (that is, in a case where the displacement does not return to the original position), the main imaging echo may be re-measured, and the reference navigator echo may be re-acquired.

In addition, the body motion correction is performed on the main imaging echo collected while it is determined that the body motion influence is present (S46). As a method for the body motion correction, for example, several methods are known such as a method of discarding the main imaging echo in a case where the body motion is large, zero-filling a portion of k-space data that remains unmeasured as a result, and performing reconstruction, a method of performing estimation processing on unmeasured data using computational operations based on a parallel imaging (PI) method and performing reconstruction, and a method of performing reconstruction by performing repeated computational operations such as compressed sensing, and these known methods can be employed. Additionally, in a case where the number of main imaging echoes to be removed is too large or in a case where the data corresponds to the low-frequency data of the k-space, re-measurement may be performed.

Processing differs depending on which method is employed; however, in this stage, the main imaging echo collected in a case where there is a body motion influence is labeled as unusable for the image reconstruction processing or is removed.

In the processing 1, by not performing the frequency variation correction while the body motion that affects the frequency variation correction is present, it is possible to prevent the frequency variation correction from being inaccurate, such as overcorrection, due to the influence of the body motion. In addition, by performing the body motion correction, it is possible to perform correction including misregistration caused by the frequency variations, thereby suppressing deterioration in image quality.

### Processing 2

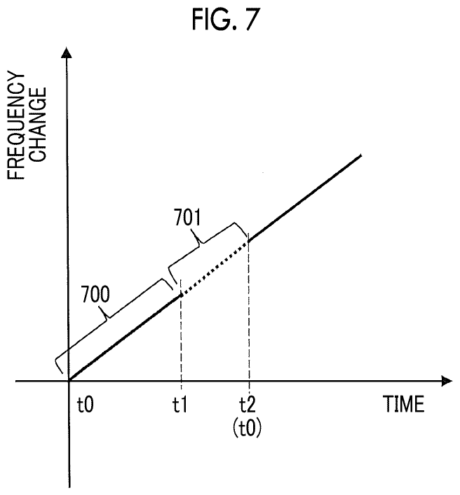

In the case of the processing 2, as shown in FIG. 5, the correction value to be used for the center frequency correction is estimated from the correction value obtained previously (S47). The estimation of the correction value can be performed by approximating the frequency variations, that is, the variations in the phase difference, with a linear function and extrapolating the phase difference. This state is shown in FIG. 7. In the graph of FIG. 7, the horizontal axis represents time, and the vertical axis represents a change in frequency (the amount of phase change). As shown in FIG. 7, in a case where there is no body motion influence, the frequency changes in a manner close to a linear function. Therefore, in a case where a change 700 has been obtained up to t1, a change 701 after time point t1 when the body motion occurs can be estimated by extrapolating this straight line. The estimation of the correction value is performed until the body motion is no longer present (up to t2 in FIG. 7), the estimated correction value is set (S444), and the next main imaging echo is acquired (S445).

In the repetition of the processing for each contrast navigator echo (S44 to S45), in a case where it is determined in the determination step S441 that there is no body motion influence, the flow returns to perform the original calculation of the amount of phase change instead of the estimation step (S47) (S442 and S443). In a case where the deviation between the calculated correction value and the immediately preceding estimated correction value is large when the amount of phase change and the correction value are calculated by returning to the original processing, the calculated correction value may be set as it is, but the reference navigator echo may be acquired again, and thereafter, the amount of phase change and the correction value may be calculated using the new reference navigator echo.

In the processing 2, the correction value is estimated while the body motion that affects the frequency variations is present, and the frequency variations are corrected. Therefore, the frequency variation correction can be continuously performed without being affected by the body motion, thereby suppressing the occurrence of misregistration in almost real time.

### Processing 3

In the processing 3, the correction value is corrected based on the body motion information obtained from the camera video, instead of estimating the correction value while it is affected by the body motion. In this case, the processing flow is the same as the flow shown in FIG. 5 except that the content of the processing of S47 in FIG. 5 changes from “estimating the correction value” to “correcting the correction value”. Therefore, FIG. 5 is referred to for the processing 3.

As for which of the three processing described above, the processing 1 to the processing 3, is to be executed, any one may be set in advance as basic processing, and then any one may be selectable by the user, or the processing may be automatically switched based on the magnitude or the duration of the body motion.

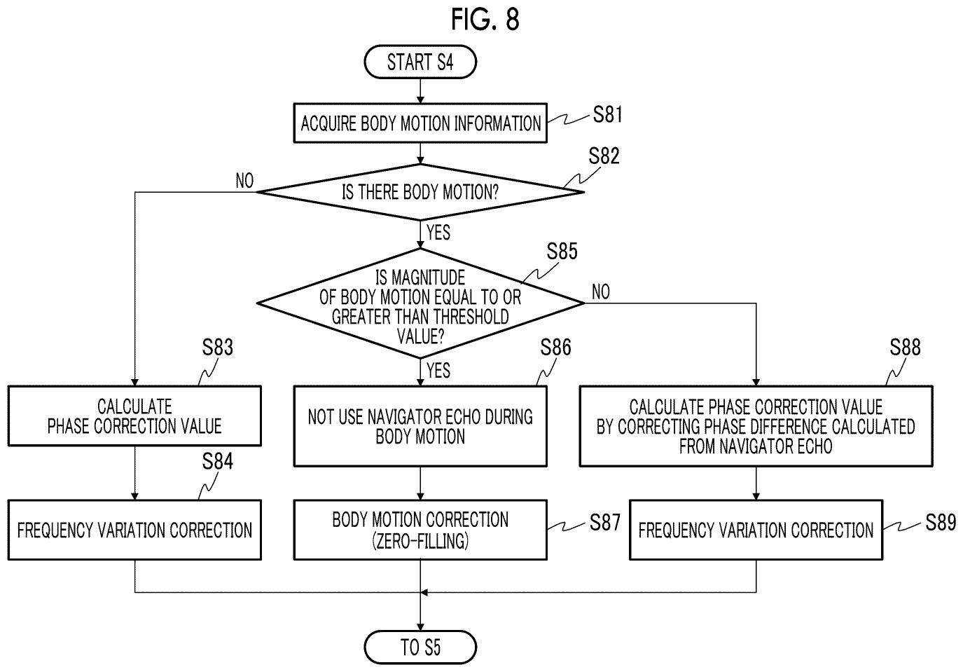

For example, as shown in FIG. 8, a threshold value is set for the magnitude of the body motion, and in a case where it is determined that there is no body motion (S82) from the body motion information (S81) obtained from the body motion processing unit 240, the phase correction value is calculated in accordance with steps S442 to S444 of FIG. 4 (S83), and the frequency variation correction is performed (S84). In a case where it is determined that there is a body motion (S82) and the body motion exceeds the threshold value (S85), as the processing 1, the navigator echo during the body motion is not used and the frequency variation correction is not performed (S86), and only the body motion correction is performed (S87). In a case where there is a body motion influence, but the magnitude of the body motion is equal to or less than the threshold value (S85), as the processing 2 or the processing 3, the correction value may be estimated or corrected, and the frequency variation correction may be performed (S88, S89).

Additionally, the processing 2 assumes that enough frequency change data to use the linearity of the frequency change is obtained, but the processing 3 has the advantage of being applicable even in a state in which such data accumulation is not present. Meanwhile, since there is a slight time lag between the acquisition of the body motion information and the calculation and setting of the correction value, it is preferable to use the estimated correction value of the processing 2 in a case where the body motion changes rapidly or in a case where the body motion changes instantaneously. Therefore, the processing 2 for estimation and the processing 3 for correction may be switched based on the elapsed time from the reference navigator echo, the number of contrast navigator echoes acquired after the reference navigator echo, or the like.

In addition, the body motion correction performed in the processing 1 may be performed in the processing 2 and the processing 3, and in this case as well, the body motion correction may be automatically performed by determining the magnitude thereof, or the user may select whether or not the body motion correction is necessary.

As described above, the main imaging echo is acquired while the frequency variation correction and the body motion correction are appropriately performed by referring to the body motion information, and in a case where the main imaging echo that can be finally reconstructed is collected, the image generation unit 220 performs image reconstruction using the collected main imaging echo (FIG. 3: S7). Here, upon the body motion correction, in a case where the main imaging echo removed based on the body motion information is present, the image reconstruction is performed in accordance with a predetermined reconstruction method during under-sampling.

According to the present embodiment, in a case where it is determined that there is an influence of the body motion by referring to the body motion information, the navigator echo acquired during that period is not used for calculating the correction value, or the navigator echo is used to correct the correction value, thereby setting the correction value for the frequency variations. As a result, it is possible to separate the amount of phase change associated with the frequency variations obtained from the navigator echo from the influence of the body motion, thereby performing accurate frequency variation correction.

### Modification Example of Embodiment 1

In Embodiment 1, a case has been described in which the frequency variation correction is performed using the correction value calculated using the contrast navigator echo acquired immediately after the body motion detection, but overcorrection may occur due to a time lag between the body motion detection and the reflection of the correction using the correction value. In the present modification example, a function of correcting the overcorrection is added to the computing unit 20A (correction value calculation unit 230).

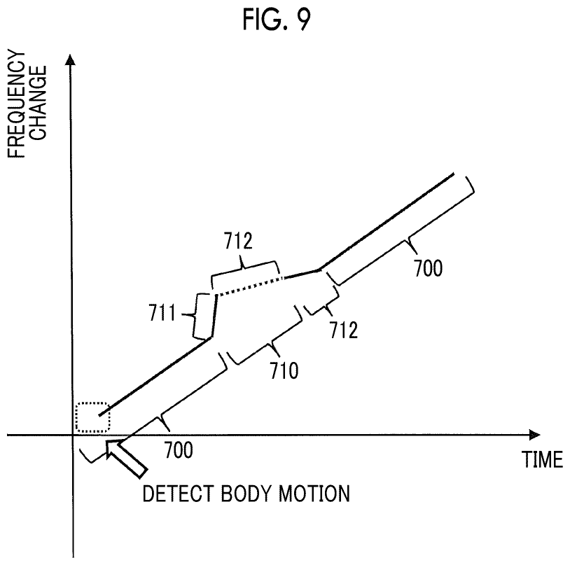

FIG. 9 shows a state of frequency variations in a case where overcorrection occurs. As shown in FIG. 9, in a case where there is no body motion influence, the frequency variations change almost linearly (700 in FIG. 9); however, in a case where the phase change caused by the body motion is added to the navigator echo, the correction value calculated using the navigator echo includes the phase change caused by the body motion. That is, this results in overcorrection 711 for the frequency variation correction.

In a case where it is determined that there is a body motion influence, the correction value calculation unit 230 estimates and corrects the correction value set before the determination, from the frequency change 700 in a case where there is no body motion influence. Upon this correction, for example, correction is performed to continuously change until it is determined that there is no body motion influence, from the correction value for the overcorrection 711 to the correction value (obtained by extrapolating the straight line) for the frequency change 700. After it is determined that there is no body motion influence, but before the correction value is calculated and set using the navigator echo acquired in a case where there is no body motion influence, an uncorrected portion 712 remains, similar to the overcorrection that has occurred. In this case, the reference navigator echo may be reacquired at a time point when it is determined that there is no body motion influence, but the uncorrected portion of the overcorrection 711 may be corrected here, and then the reference navigator echo may be reacquired.

According to the present modification example, it is possible to correct the overcorrection due to the time lag between the determination processing with reference to the body motion information and the correction value setting processing, and it is possible to improve the accuracy of the frequency variation correction.

### Embodiment 2

In Embodiment 1, the center frequency variation correction is determined mainly in response to the magnitude of the body motion as the body motion information, but in the present embodiment, the frequency variation correction is performed in response to the periodic motion included in the body motion information.

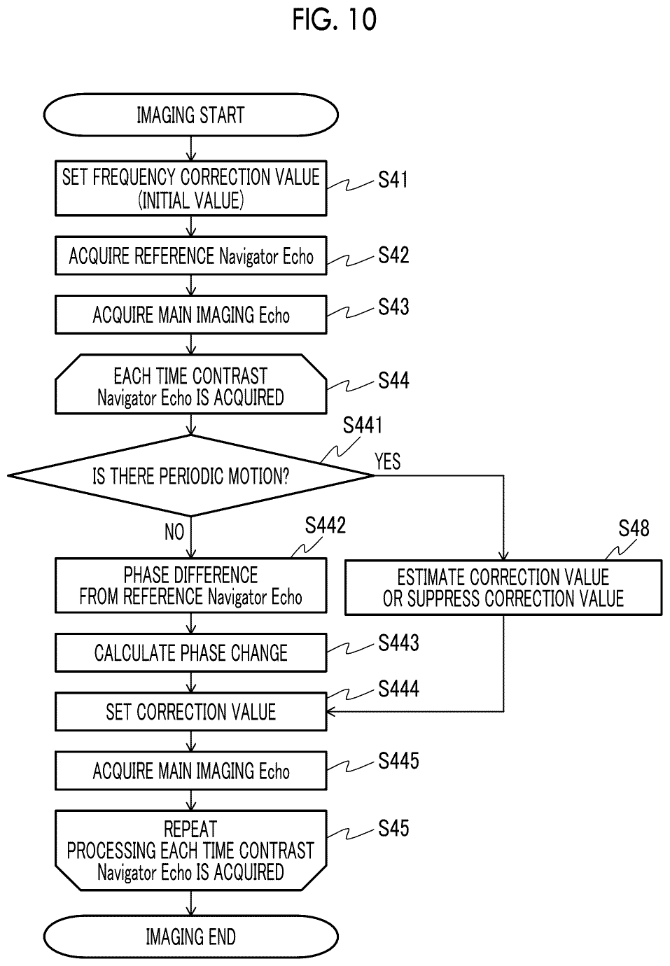

The present embodiment will be described with reference to FIG. 10 for the processing flow of the present embodiment. In FIG. 10, the same processing as in FIG. 5 will not be repeated, and different points will be described.

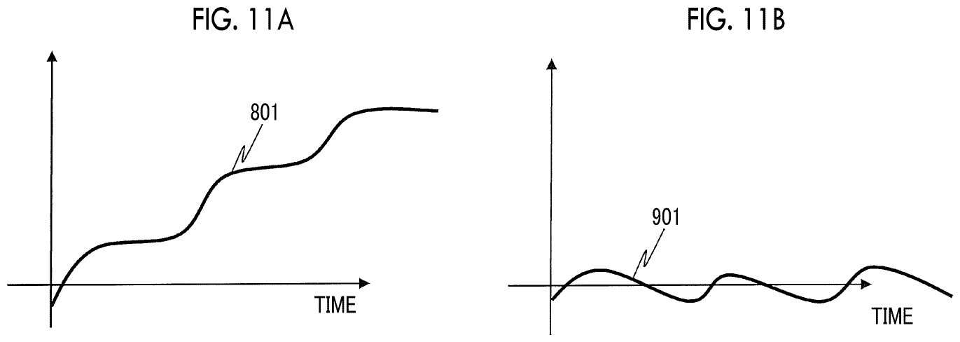

In the calculation of the correction value, in a case where the amount of phase change (the frequency change corresponding to the amount of phase change) is obtained using the reference navigator echo and the contrast navigator echo when there is a periodic motion, as shown in FIGS. 11A and 11B, a frequency change 801 is a change in which a periodic motion 901 (obtained by converting the displacement in the real space into the frequency variations), which is the body motion, is superimposed. However, since the body motion information is collected sequentially, it is not possible to determine whether or not the body motion has a relatively small magnitude and is a periodic motion at a time point when the body motion is detected. In the present embodiment, in the determination step (S441) in the calculation of the correction value, a threshold value for a relatively gentle body motion corresponding to the magnitude of the displacement caused by the periodic motion is set instead of a threshold value for the abrupt body motion (for example, FIG. 6A), and in a case where there is a body motion and the body motion is equal to or less than the set threshold value, it is determined that the body motion is the periodic motion (S441), and the correction corresponding to the periodic motion is performed (S48).

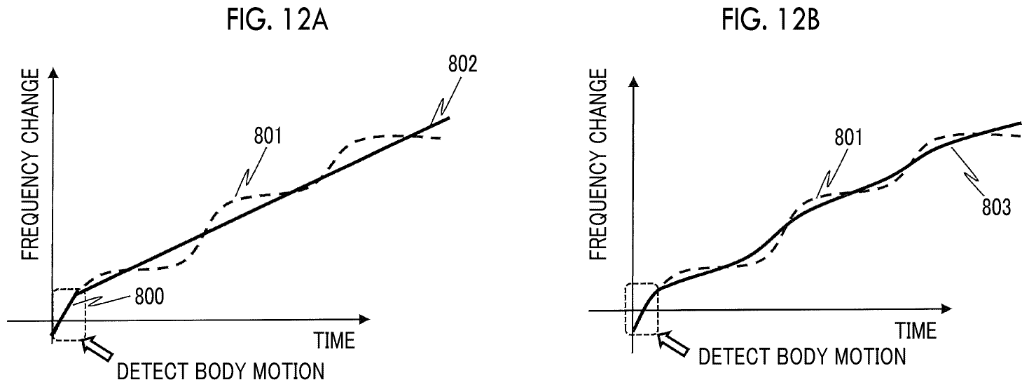

As in the processing 2 of Embodiment 1, for the correction for the periodic motion, a method of performing extrapolation using the linearity (assuming a linear function) of the frequency change collected previously (FIG. 12A) can be employed, or a method of suppressing the change in the correction value (FIG. 12B) such as limiting the change in the correction value to “several percent” or less can be employed. The degree of suppression may be calculated based on the change in a case where the body motion information (information on the period or the magnitude of the periodic motion) is collected prior to imaging, or a default value (for example, several percent to 10%) may be set to ensure that the desired phase change is not obscured.

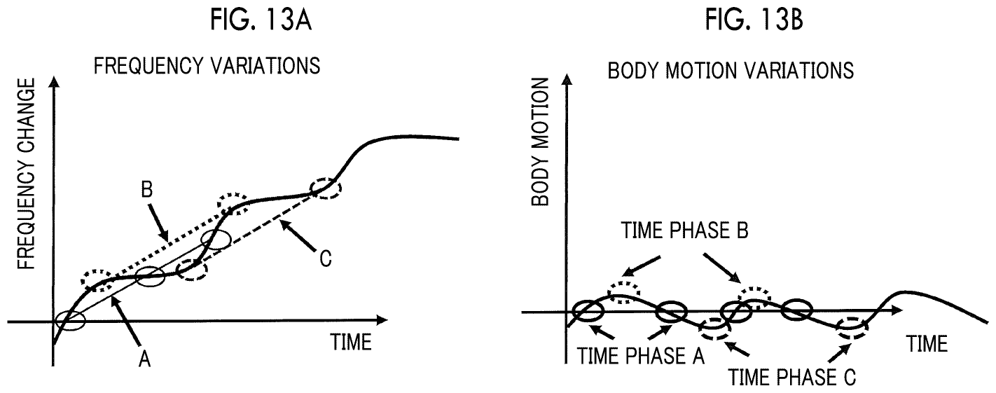

As still another method, the body motion information may be collected until the period information of the periodic motion can be acquired, and the correction value may be calculated based on the magnitude (amplitude) and the period of the periodic motion. In this case, as shown in FIG. 13B, first, the body motion variations are divided into a plurality of ranges (for example, three ranges), and for each range, time phases (for example, a time phase A, a time phase B, and a time phase C) are acquired in which the magnitude of the displacement (body motion value) is the same. Next, for the variations in the frequency change corresponding to the correction value as shown in FIG. 13A, a straight line (correction values A, B, and C) of the frequency change is obtained from frequency change value obtained at each time phase of the body motion variations. The frequency variation correction is performed by sequentially applying the correction values obtained from these straight lines.

For example, first, after the body motion is detected, the frequency variation correction is performed by calculating the correction value from the frequency variations obtained from the navigator echo without taking into consideration the body motion until any of the body motion values A, B, or C is calculated. First, in a case where, for example, the body motion value A is calculated, a correction value based on the body motion value A is applied until the body motion value B or the body motion value C, or the second body motion value A is calculated. Next, in a case where the body motion value B is calculated, a correction value based on the body motion value B is applied until the body motion value C, the body motion value B, or the second body motion value A is calculated. Further, in a case where the next body motion value A is calculated, a correction value based on the body motion value A is applied until the body motion value C, the second body motion value B, or the third body motion value A is calculated. Similarly, each time the body motion value is calculated in time-series manner, the correction value based on the body motion value is applied.

This method has a certain time lag between the acquisition of the body motion information and the frequency variation correction, but the accuracy of the frequency variation correction can be further enhanced as compared with the suppression of the correction value mentioned above.

According to the present embodiment, even in a case where there is a periodic motion in the imaging site, it is possible to remove the periodic motion mixed in the amount of phase change calculated from the navigator echo or to reduce the influence of the periodic motion, and it is possible to accurately obtain the amount of phase change corresponding to the frequency variations. As a result, by separating the misregistration caused by the variations in the center frequency from the misregistration caused by the body motion (periodic motion), accurate correction can be performed.

### Embodiment 3

The present embodiment is a suitable embodiment for a case where a localized abrupt body motion occurs in an imaging region or a vicinity thereof, a case where a periodic motion such as a respiratory motion affects only a part of the imaging region, or the like, and by referring to a localized body motion site and the sensitivity of a plurality of small coils (channels) that constitute the receive coil, the navigator echo of the small coil to be used for calculating the correction value is selected or discarded, and the correction value for the frequency variation correction is calculated.

In the MRI apparatus, a multi-channel or multi-array coil in which a plurality of small coils are arranged is usually employed as the receive coil 104, and the NMR signals received by each small coil are combined using the sensitivity distribution of each small coil to reconstruct the image. The same applies to the navigator echo, and the correction value for frequency variation correction is calculated using the navigator echo collected by each of the plurality of small coils. Based on that premise, in the present embodiment, the characteristic feature is that body motion information is referred to for each small coil.

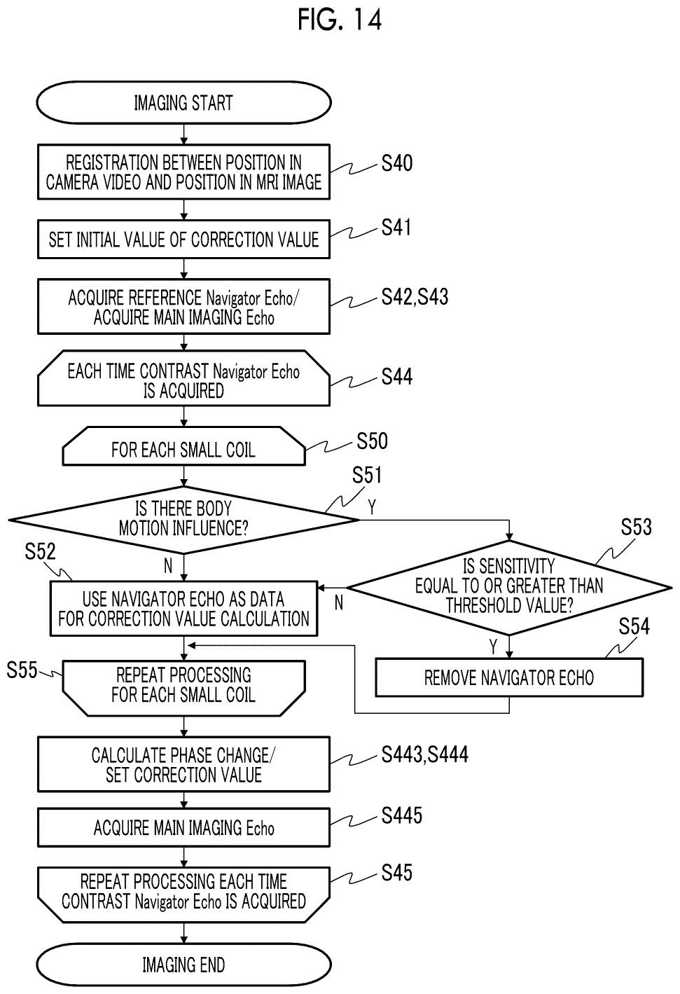

Hereinafter, the processing of the present embodiment will be described with reference to FIG. 14.

As shown in FIG. 14, in the processing of the present embodiment, a repeated step (S50 to S55) of the processing for each small coil is inserted between the repeated processing steps (S44 to S45) for each contrast navigator echo with respect to the processing of Embodiment 1 shown in FIGS. 4 and 5. In addition, although not an essential step, a step S40 of performing registration between the coordinates of the imaging space and the coordinates of the camera video may be added. Other steps are the same as those of Embodiment 1 or Embodiment 2, and the following description will focus on processing of different steps.

In the present embodiment, first, the position of the imaging region in the camera video acquired by the body motion processing unit 240, for example, the positions of a plurality of feature points in the ROI (the positions on the coordinates of the camera image), is associated with the position of each small coil of the receive coil attached to the subject (the position on the real space coordinates or the position on the coordinates of the MRI image) (S40: registration processing). This processing can be performed, for example, by providing an identifiable marker at a position (for example, a center of a conductive loop) of each small coil of the receive coil attached to the subject 50 and associating the camera video that captures these markers with the marker position on the real space. Additionally, a relationship (a relationship in image coordinates) between a sensitivity map of the receive coil (small coil) acquired in advance and an imaging position may be stored in advance, and registration between the imaging position on the image and the imaging position in the coordinates of the camera image may be performed.

The registration processing of S40 may be omitted in a case where the relationship between the coil and the attached site, such as a head coil, is known in advance.

After performing the registration mentioned above as necessary, the imaging is started, the main imaging echo and the reference navigator echo are acquired, and the contrast navigator echo is acquired (S41 to S44). Since the contrast navigator echo is received by each small coil, it is determined whether or not the navigator echo obtained for each small coil can be employed for calculating the correction value with reference to the body motion information (S50, S51, S52).

Here, as described in the above-mentioned embodiment, the body motion processing unit 240 detects the displacement at each position in, for example, the imaging site (for example, the ROI) by obtaining the displacement vectors from the camera video for each frame using a method such as optical flow. Therefore, the displacement at the position associated with the small coil is obtained as the body motion information.

The correction value calculation unit 230 determines whether or not there is a displacement equal to or greater than a predetermined threshold value (displacement threshold value) in any of the imaging regions, from the body motion information for each site through analysis of the camera video by the body motion processing unit 240 (S51). As a result, in a case where it is determined that there is a body motion influence in any of the imaging regions, it is determined whether or not the sensitivity of the small coil to be processed is equal to or greater than a predetermined threshold value (sensitivity threshold value) at the position (body motion site) where it is determined that there is a body motion influence (S53). In a case where the sensitivity is equal to or greater than the predetermined sensitivity threshold value, the navigator echo collected by the small coil is not used for the amount of phase change (S54). For example, in a case where a portion of the imaging region or a site in proximity to the imaging region is moving due to convulsions or the like, a small coil having high sensitivity to that site is discriminated based on the body motion information of that site and the sensitivity of the small coil.

In a case where there is no body motion influence or in a case where there is a body motion influence in a part of the imaging region or the vicinity thereof but the sensitivity to that part or the vicinity is low, the navigator echo acquired by the small coil is used as it is for calculating the correction value (S52).

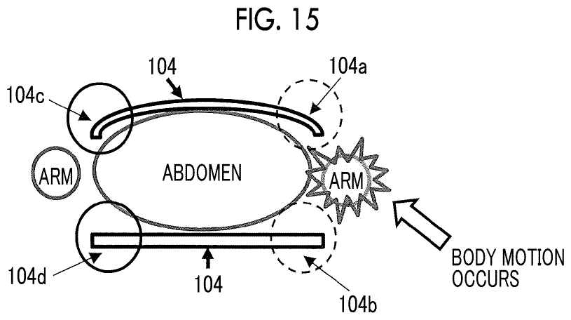

FIG. 15 shows a state of selecting the small coil in these determination steps. The example shown in FIG. 15 is an example in which the abdomen of the subject 50 is imaged, and the receive coil 104 is disposed to cover the abdomen of the subject. Here, in a case where the arm (in FIG. 15, the right arm) close to the abdomen suddenly moves, the navigator echoes acquired by small coils 104a and 104b that are disposed near a body motion occurrence site and that have a predetermined level of sensitivity to the body motion occurrence site are not used for calculating the correction value. On the other hand, since small coils 104c and 104d that are located far from the right arm are far from the body motion occurrence site and have low sensitivity to the body motion occurrence site, the navigator echoes acquired by these small coils are used for calculating the correction value.

After the above processing of S51 to S54 is performed on the navigator echoes obtained by the plurality of small coils that constitute the receive coil, the navigator echoes that are not removed are summed up using a complex addition, and the amount of phase change is calculated (S443), and the correction value is calculated and set (S444). The frequency variation correction is performed using the correction value to acquire the main imaging echo (S445). Upon the calculation of the amount of phase change, instead of adding the navigator echoes obtained for each small coil, by calculating the amount of phase change from the reference navigator echo and the contrast navigator echo for each small coil, the amount of phase change for each small coil can be averaged.

After that, repeating the processing of S44 to S45 each time the contrast navigator echo is acquired is the same as in Embodiment 1 or Embodiment 2.

In addition, although not shown, in a case where there is a body motion equal to or greater than the predetermined threshold value at many positions of the imaging region, the number of contrast navigator echoes to be used for the correction value decreases. Therefore, as in Embodiment 1, it is also possible to not perform the frequency variation correction (processing 1), or estimate (processing 2)/correct (processing 3) the correction value.

Further, similarly, the body motion correction may be performed separately from the frequency variation correction.

According to the present embodiment, in a case where there is a body motion in a part of the imaging site or the vicinity thereof, the navigator echo collected by the small coil having a high sensitivity to that portion is excluded, so that it is possible to perform the frequency variation correction that is less affected by the body motion.

### Modification Example of Embodiment 3

In Embodiment 3, the navigator echo obtained by the small coil having a high sensitivity to the body motion site is not used for calculating the frequency variation correction. However, in a case of adding the navigator echo obtained by each small coil or in a case of combining the amounts of phase change calculated from the navigator echoes, it is also possible to calculate the correction value by weighting the navigator echo according to the distance or the sensitivity of each small coil in the body motion site.

According to Embodiment 3 and the modification example thereof, in a case where a localized body motion occurs in the subject, the information from the small coil having a high sensitivity to that localized portion is not used for the frequency variation correction or is used with suppression, thereby enabling the frequency variation correction to be performed with the influence of the body motion eliminated.

### EXPLANATION OF REFERENCES

1: MRI apparatus
10: imaging unit
20: processor
20A: computing unit
20B: control unit
210: imaging control unit
220: image generation unit
230: correction value calculation unit
240: body motion processing unit

What is claimed is:

1. A magnetic resonance imaging apparatus comprising:
an imaging unit that collects a nuclear magnetic resonance signal generated from a subject through nuclear magnetic resonance; and
one or more processors which is configured to reconstruct an image of the subject using the nuclear magnetic resonance signal, and to collect body motion information of the subject,
wherein the imaging unit collects a navigator echo for detecting a variation in a center frequency of the nuclear magnetic resonance,
the one or more processors calculate a correction value for correcting the variation in the center frequency by using a phase change of the navigator echo collected by the imaging unit, and calculate the correction value by eliminating an influence of a body motion with reference to the collected body motion information.

2. The magnetic resonance imaging apparatus according to claim 1,
wherein the one or more processors collect the body motion information by analyzing a video from a camera that detects the body motion of the subject.

3. The magnetic resonance imaging apparatus according to claim 1,
wherein the one or more processors compare a magnitude of the body motion with a predetermined threshold value, and does not use the navigator echo collected in a case where the magnitude of the body motion is equal to or greater than the threshold value, for calculating the correction value.

4. The magnetic resonance imaging apparatus according to claim 3,
wherein the one or more processors do not calculate the correction value in a case where the magnitude of the body motion is equal to or greater than the threshold value, and perform body motion correction on a nuclear magnetic resonance signal for image reconstruction of the subject or the image of the subject using the body motion information.

5. The magnetic resonance imaging apparatus according to claim 3,
wherein the one or more processors estimate a correction value during a period from when the magnitude of the body motion is equal to or greater than the threshold value until the magnitude of the body motion falls below the threshold value, based on a correction value calculated before the magnitude of the body motion is equal to or greater than the threshold value.

6. The magnetic resonance imaging apparatus according to claim 1,
wherein the one or more processors use the body motion information to correct a correction value calculated using the navigator echo collected in a case where a magnitude of the body motion is equal to or greater than a predetermined threshold value.

7. The magnetic resonance imaging apparatus according to claim 1,
wherein the one or more processors calculate the correction value by suppressing, in a case where the collected body motion information includes a periodic motion, a phase change caused by the periodic motion included in the phase change of the navigator echo.

8. The magnetic resonance imaging apparatus according to claim 7,
wherein the one or more processors use a value obtained by multiplying the correction value calculated from the phase change of the navigator echo by a predetermined coefficient as the correction value for correcting the variation in the center frequency.

9. The magnetic resonance imaging apparatus according to claim 7,
wherein the one or more processors calculate the correction value using a plurality of the navigator echoes acquired at the same time phase of the periodic motion.

10. The magnetic resonance imaging apparatus according to claim 1,
wherein the imaging unit includes a receive coil consisting of a plurality of small coils that receive the nuclear magnetic resonance signals, and
the one or more processors calculate the correction value using the navigator echo received by each of the plurality of small coils.

11. The magnetic resonance imaging apparatus according to claim 10,
wherein the one or more processors acquire a site where the body motion occurs from the body motion information, and selects a navigator echo of a small coil to be used for calculating the correction value by using the site where the body motion occurs and sensitivity of the plurality of small coils.

12. A center frequency correction method of correcting a variation in a center frequency of an emitted radiofrequency in a magnetic resonance imaging apparatus, the method comprising:
a step of calculating a correction value for the center frequency by calculating a phase difference using two or more nuclear magnetic resonance signals acquired as navigator echoes from a subject during an examination; and
a step of collecting body motion information from a device that detects a body motion of the subject during the examination,
wherein, in the step of calculating the correction value, the correction value is calculated by eliminating an influence of the body motion with reference to the body motion information.
